(19) United States
(12) Patent Application Publication
(10) Pub. No.: US 2016/0035893 A1
(43) Pub. Date: Feb. 4, 2016

(54) PIXEL STRUCTURE AND MANUFACTURING METHOD THEREOF

(71) Applicant: Chunghwa Picture Tubes, LTD., Taoyuan County (TW)

(72) Inventors: Chin-Tzu Kao, Changhua County (TW); Ya-Ju Lu, New Taipei City (TW); Kuo-Wei Wu, New Taipei City (TW); Cheng-Fang Su, New Taipei City (TW)

(21) Appl. No.: 14/519,148

(22) Filed: Oct. 21, 2014

(30) Foreign Application Priority Data
Aug. 1, 2014 (TW) 103126369

(51) Int. Cl. H01L 29/786; H01L 21/02; H01L 27/12; H01L 21/383; H01L 29/66; H01L 29/423

(52) U.S. Cl. CPC H01L 29/7869; H01L 29/66969; H01L 29/42356; H01L 27/1225; H01L 27/1288; H01L 21/383; H01L 21/02565

(57) ABSTRACT

A manufacturing method of a pixel structure is provided, which includes following steps. A gate and a gate insulating layer are formed on a substrate. A source and a drain are formed on the gate insulating layer. A first and a second semiconductor pattern are formed on the gate insulating layer. The first semiconductor pattern is located above the gate, wherein the first semiconductor pattern contacts the source and the drain. The second semiconductor pattern contacts the drain. A mask which exposes both sides of the first semiconductor pattern is formed on the first semiconductor pattern. A treatment procedure is performed, so that a first and a second conductive region are formed at both sides of the exposed first semiconductor pattern, and the second semiconductor pattern is formed into a pixel electrode pattern. The first semiconductor pattern which is covered by the mask is formed into a channel region.

### CROSS-REFERENCE TO RELATED APPLICATION

This application claims the priority benefit of Taiwan application serial no. 103126369, filed on Aug. 1, 2014. The entirety of the above-mentioned patent application is hereby incorporated by reference herein and made a part of this specification.

### BACKGROUND OF THE INVENTION

1. Field of the Invention

The invention is related to an electronic device and a manufacturing method thereof, and more particularly to a pixel structure and a manufacturing method thereof.

2. Description of Related Art

A metal oxide semiconductor material has high electron mobility and high transparency and therefore is suitable for being used in manufacturing a pixel structure. Among known methods for manufacturing the pixel structure using the metal oxide semiconductor, a gate, a gate insulating layer and a channel are sequentially formed on a substrate, and normally an etch stopper layer is additionally formed on the channel. Thereafter, the etch stopper layer is patterned using an additional mask to form a channel protection pattern that covers a portion of the channel. Subsequently, a source and a drain of a thin film transistor are formed, followed by the formation of a pixel electrode. However, in that case, a plurality of photomask lithographic steps are required to be performed, which consequently brings negative impact on lowering manufacturing costs and improving productivity.

### SUMMARY OF THE INVENTION

The invention provides a method of manufacturing a pixel structure with less photomask lithographic steps.

The invention provides a pixel structure obtained with less photomask lithographic steps.

The invention provides a method of manufacturing a pixel structure, including the following steps. A gate is formed on a substrate. A gate insulating layer is formed on the substrate to cover the gate. A source and drain are formed on the gate insulating layer. A first semiconductor pattern and the second semiconductor pattern are formed on the gate insulating layer. The first semiconductor pattern is located above the gate, and the first semiconductor pattern contacts the source and drain. The second semiconductor pattern contacts the drain. A mask is formed on the first semiconductor pattern; the mask exposes both sides of the first semiconductor pattern. A treatment procedure is performed so that a first conductive region and a second conductive region are formed at both sides of the exposed first semiconductor pattern, and the second semiconductor pattern is formed into a pixel electrode pattern. The first semiconductor pattern which is covered by the mask is formed into a channel region, wherein the channel region is located between the first conductive region and the second conductive region. The first conductive region is electrically connected to the source. The second conductive region is electrically connected to the drain. The pixel electrode pattern is electrically connected to the drain.

The invention provides a pixel structure, including a substrate, a gate, a gate insulating layer, a source and a drain, a semiconductor pattern and a pixel electrode pattern. The gate is located on the substrate. The gate insulating layer covers the gate. The source and drain are located on the gate insulating layer. The semiconductor pattern is located above the gate and contact the source and drain. The semiconductor pattern includes the first conductive region, the second conductive region, and the channel region. The first conductive region which is located at one side of the semiconductor pattern is electrically connected to the source. The second conductive region which is located at another side of the semiconductor pattern is electrically connected to the drain. The channel region is located above the gate and between the first conductive region and the second conductive region. The pixel electrode pattern has the same material and being the same film layer with the second conductive region of the semiconductor pattern, and the pixel electrode pattern is electrically connected to the drain via the second conductive region.

Based on the above, in the manufacturing method of the pixel structure of the invention, the first semiconductor pattern and the second semiconductor pattern are formed at the same time firstly. Thereafter, a treatment procedure is performed to the semiconductor pattern so that the exposed first semiconductor pattern is formed into the conductive region and the second semiconductor pattern is formed into a pixel electrode pattern. Accordingly, the manufacturing method of the pixel structure of the invention may help to reduce the photomask lithographic steps, thereby lowering manufacturing cost and improving productivity.

In order to make the aforementioned features and advantages of the disclosure more comprehensible, embodiments accompanying figures are described in detail below.

### BRIEF DESCRIPTION OF THE DRAWINGS

FIGS. 1A-1H are cross-sectional schematic views illustrating a manufacturing method of a pixel structure according to a first embodiment of the invention.

FIGS. 2A-2I are cross-sectional schematic views illustrating a manufacturing method of a pixel structure according to a second embodiment of the invention.

FIGS. 3A-3H are cross-sectional schematic views illustrating a manufacturing method of a pixel structure according to a third embodiment of the invention.

FIGS. 4A-4I are cross-sectional schematic views illustrating a manufacturing method of a pixel structure according to a fourth embodiment of the invention.

### DESCRIPTION OF EMBODIMENTS

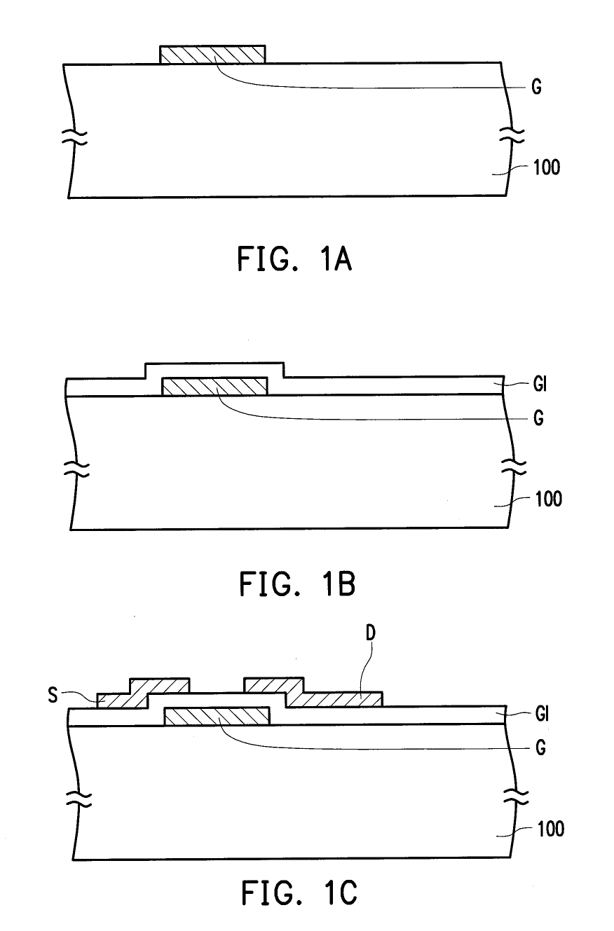

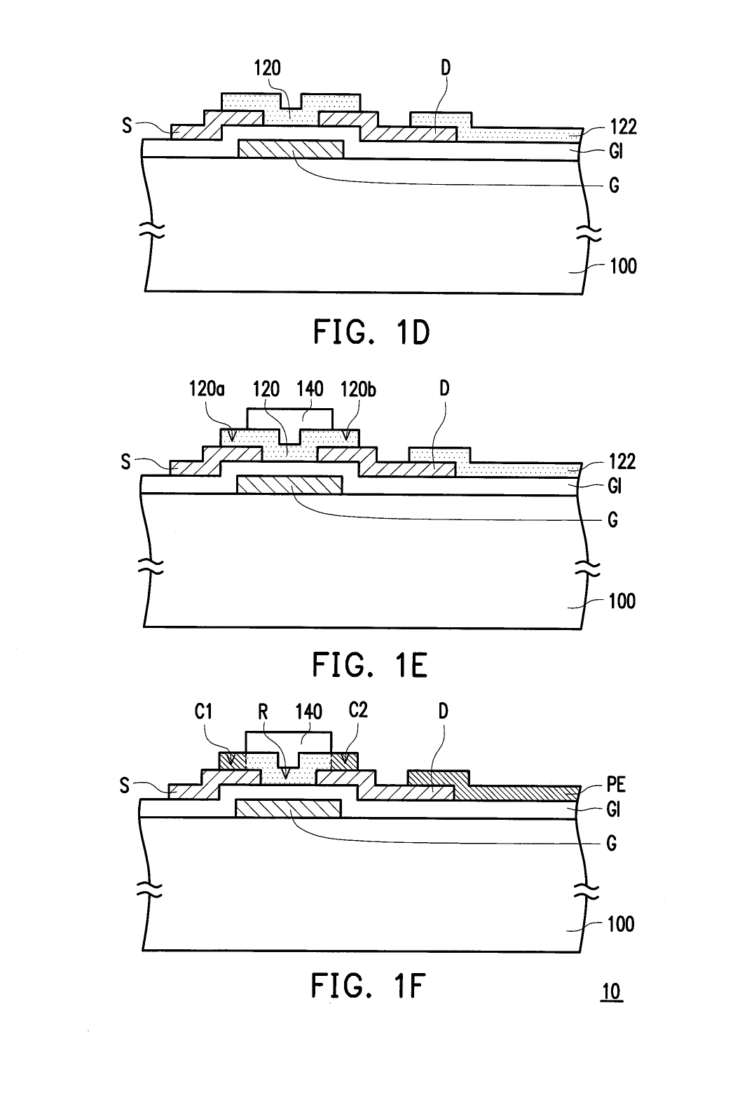

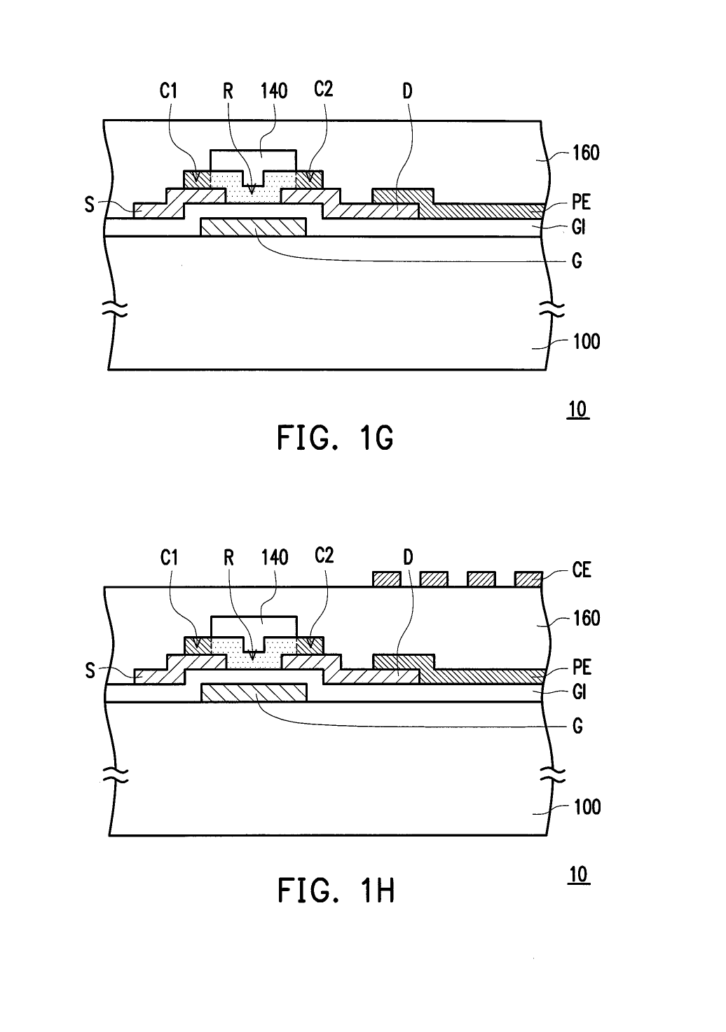

Please refer to FIG. 1A. First of all, a substrate 100 is provided. In terms of optical characteristic, the substrate 100 may be a transparent substrate or an opaque/reflective substrate. The material of the transparent substrate may be selected from glass, quartz, organic polymer, other suitable materials or a combination thereof. The material of the opaque/reflective substrate may be selected from conductive material, metal, wafer, ceramics, other suitable materials or a combination thereof. Please note that, in the case where the material of the substrate 100 is a conductive material, it is necessary to form an insulating layer (not shown) on the substrate 100 before the substrate 100 is equipped with a component of a thin film transistor in case short circuit is caused between the substrate 100 and the component of the thin film transistor.

Thereafter, a gate G is formed on the substrate 100. For example, in the embodiment, a conductive layer may be formed on the substrate 100 first; then, a photolithography and etching process is performed to the conductive layer to form the gate G. Generally, the gate G is formed of a metal material; however, the invention is not limited thereto. In other embodiments, the gate G may be formed of other conductive materials (such as alloy, metal nitride, metal oxide and metal oxynitride etc.) or a stacked layer consisting of metal and other conductive materials.

Subsequently, as shown by FIG. 1B, a gate insulating layer GI is formed on the gate G to cover the gate G The material of the gate insulating layer GI may be selected from an inorganic material (such as silicon oxide, silicon nitride, silicon oxynitride, other suitable materials or a stacked layer consisting of at least two materials mentioned above), an organic material or a combination thereof. In the embodiment, the gate insulating layer GI may fully cover gate G and the substrate 100; however, the invention is not limited thereto.

Then, as shown by FIG. 1C, a source S and a drain D are formed on the gate insulating layer GI. The source S and the drain D are separated from each other and respectively cover opposite sides of the gate insulating layer GI above the gate G. Generally, the source S and the drain D are formed of metal materials; however, the invention is not limited thereto.

As shown by FIG. 1D, a first semiconductor pattern 120 and a second semiconductor pattern 122 are formed on the gate insulating layer GI. The first semiconductor pattern 120 is formed above the gate G, and the first semiconductor pattern 120 contacts the source S and the drain D. The second semiconductor pattern 122 contacts the drain D. In the embodiment, the first semiconductor pattern 120 covers the source S and drain D, and the second semiconductor pattern 122 covers the drain D; however, the invention provides no limitation to the sequence of the formation of the source S and the drain D as well as the formation of the first semiconductor pattern 120 and the second semiconductor pattern 122, the sequence of the above formation may be adjusted depending on needs. In the embodiment, the first semiconductor pattern 120 and the second semiconductor pattern 122 are formed as described in details below; however, the invention is not limited thereto. First of all, a semiconductor layer (not shown) is formed on the gate insulating layer GI. The semiconductor layer may have a single layer or multi-layered structure, and the material thereof may be selected from amorphous silicon, polysilicon, microcrystalline silicon, silicon single crystal, metal oxide semiconductor material, other suitable materials or a combination thereof. Considering from the aspect of high transparency and modulation of high carrier concentration, in the embodiment, the material of the semiconductor layer is preferably a metal oxide semiconductor material which is selected from, for example, Indium-Gallium-Zinc Oxide (IGZO); zinc oxide (ZnO); tin oxide (SnO); Indium-Zinc Oxide (IZO); Gallium-Zinc Oxide (GZO); Zinc-Tin Oxide (ZTO); Indium-Tin Oxide (ITO) or a combination thereof; however, the invention is not limited thereto. Then, a photoresist layer (not shown) is formed on the semiconductor layer. The invention provides no limitation to the type of the photoresist layer, which may be a negative photoresist layer or a positive photoresist layer selectively. Thereafter, the photoresist layer is patterned to form a photoresist pattern (not shown); such photoresist pattern is used as a mask for patterning the semiconductor layer to form the first semiconductor pattern 120 and the second semiconductor pattern 122 (as shown by FIG. 1D). In the embodiment, the first semiconductor pattern 120 and the second semiconductor pattern 122 are aligned with the photoresist pattern.

Please refer to FIG. 1E, a mask 140 is formed on the first semiconductor pattern 120. The mask 140 covers a portion of the first semiconductor pattern 120 and exposes opposite sides 120a and 120b of the first semiconductor pattern 120. In the embodiment, the material of the mask 140 may be any suitable insulating materials. The mask 140 may protect the portion of covered the first semiconductor pattern 120 from being affected during the subsequent treatment procedure. More details are provided below.

Please refer to FIG. 1F, a treatment procedure is performed to the first semiconductor pattern 120 and the second semiconductor pattern 122 so that the both sides 120a and 120b of the exposed first semiconductor pattern 120 are respectively formed into a first conductive region C1 and a second conductive region C2, allowing the second semiconductor pattern 122 to be formed into a pixel electrode pattern PE. In the embodiment, the above treatment procedure is a hydrogen plasma doping treatment; however, the invention is not limited thereto. In other embodiments, the treatment procedure may also be a nitrogen plasma doping treatment, an ultra-violet (UV) curing treatment or a heating treatment. To be specifically, since the material of the first semiconductor pattern 120 and the second semiconductor pattern 122 of the embodiment is a metal oxide semiconductor material, and the carrier concentration of the material may be modulated via the above treatment procedure, the exposed metal oxide semiconductor region may be formed into the first conductive region C1 and the second conductive region C2. In addition, since the metal oxide semiconductor material also has high transparency, the second semiconductor pattern 122 treated by the treatment procedure may also be formed into a pixel electrode pattern PE used for a display panel. In the embodiment, the first conductive region C1 covers the source S to be electrically connected to the source S. The second conductive region C2 covers the drain D to be electrically connected to the drain D. The pixel electrode pattern PE covers the drain D, and the pixel electrode pattern PE is electrically connected to the drain D via the second conductive region C2; however, the invention is not limited thereto.

To the contrary, the metal oxide semiconductor region covered by the mask 140 is protected by the mask 140 from being affected during the treatment procedure, thereby retaining the semiconductor characteristic to be formed into a channel region R. As shown by FIG. 1F, the channel region R is located above the gate G and between the first conductive region C1 and the second conductive region C2. After the above steps are performed, the manufacture of a pixel structure 10 of the embodiment is completed.

In the embodiment, the pixel structure 10 may be applied in, for example, a liquid crystal display (LCD), which should not be construed as a limitation to the invention. When the pixel structure 10 is applied in the display panel, please refer to FIG. 1G, a protecting layer 160 may be further formed on the gate insulating layer GI. In the embodiment, the protecting layer 160 covers the mask 140. Thereafter, as shown by FIG. 1H, a common electrode pattern CE may be formed on the protecting layer 160. The common electrode pattern CE is located above the pixel electrode pattern PE. When the pixel structure 10 is applied in a fringe field switching (FFS) LCD, at least one of the pixel electrode pattern PE and the common electrode pattern CE may have a plurality of slits and a plurality of branch electrode patterns. In the embodiment, the pixel electrode pattern PE is a block-shaped electrode pattern, and the common electrode pattern CE has a plurality of branch electrode patterns. However, the pixel electrode pattern PE and the common electrode pattern CE may also be an electrode pattern in other shapes.

Specifically, in the manufacturing method of the pixel structure of the embodiment, the first semiconductor pattern 120 and the second semiconductor pattern 122 consisting of a metal oxide semiconductor material are formed first at the same time. Thereafter, the both sides 120a and 120b of the exposed first semiconductor pattern 120 are formed into the first conductive region C1 and the second conductive region C2 via the hydrogen plasma doping treatment or the like; meanwhile, the second semiconductor pattern 122 is formed into the pixel electrode pattern PE. Furthermore, the channel region R is also formed in the covered first semiconductor pattern 120 during the above step. Compared with conventional manufacturing methods of the pixel structure, the manufacturing method of the pixel structure of the embodiment may allow the channel region R and the pixel electrode pattern PE to be formed at the same time; in that case, the above method helps to reduce the photomask lithographic steps for manufacturing the pixel structure 10, thereby lowering the manufacturing cost and improving productivity.

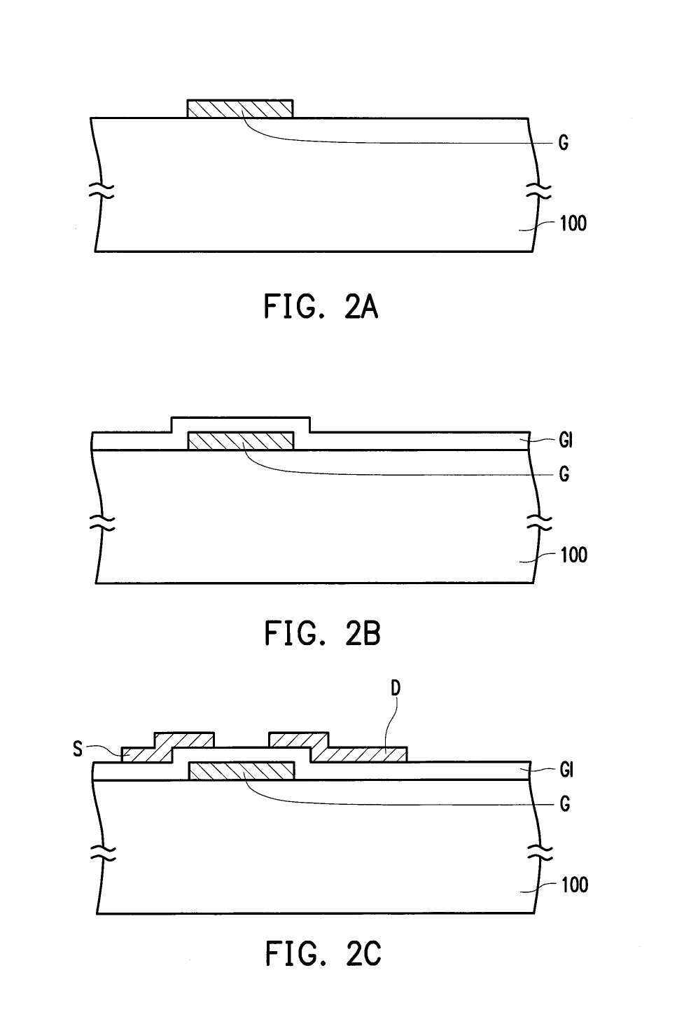

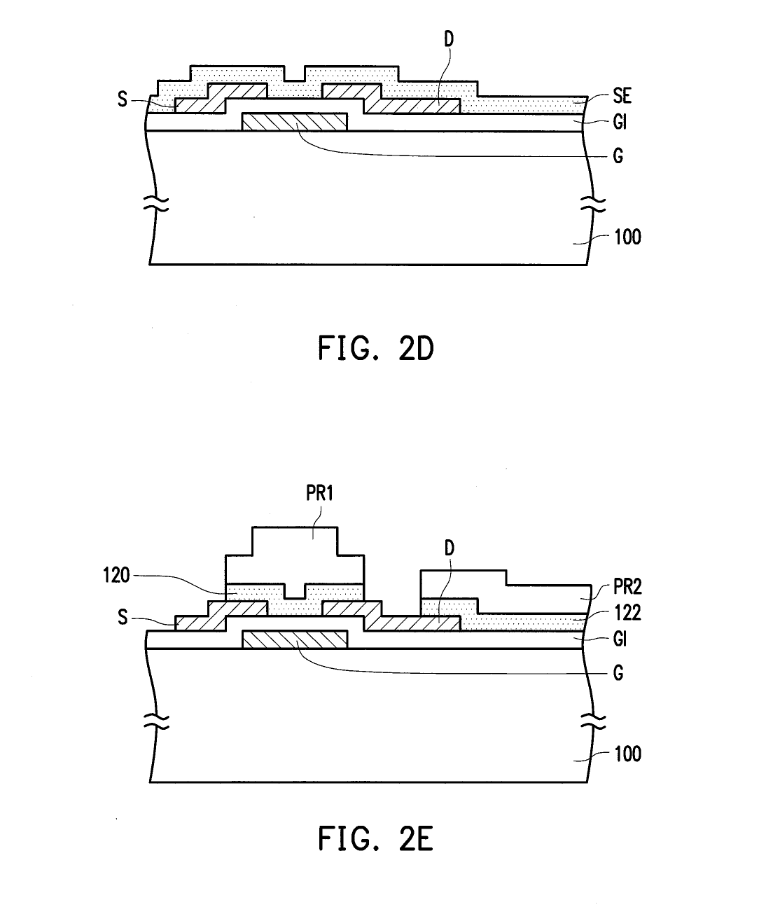

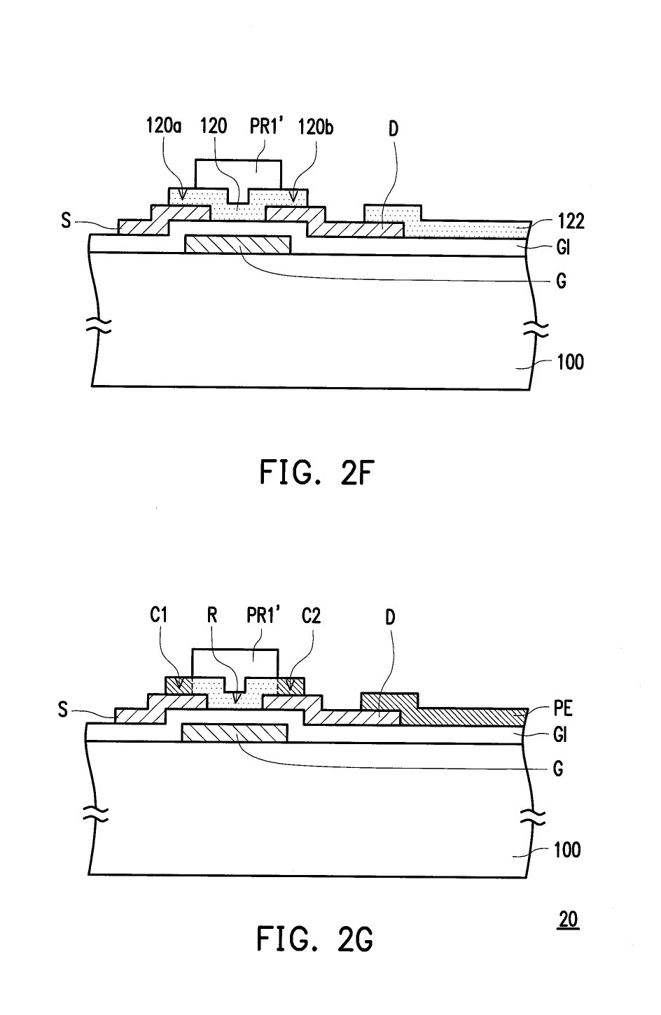

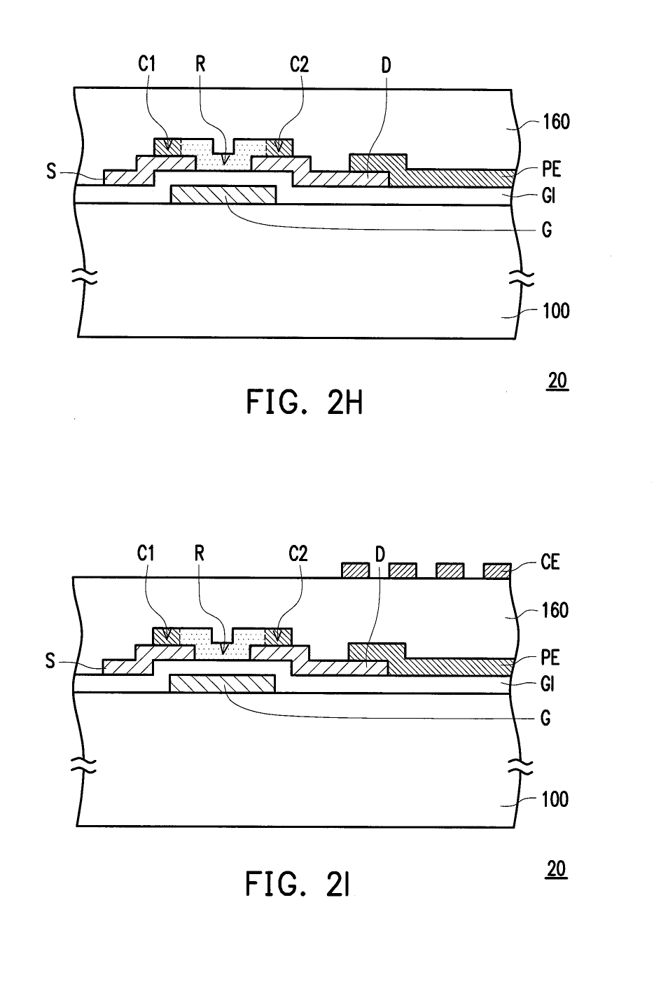

FIGS. 2A-2I are cross-sectional schematic views illustrating a manufacturing method of a pixel structure according to a second embodiment of the invention. The manufacturing method of the pixel structure in FIGS. 2A-2I is similar to the manufacturing method of the pixel structure in FIGS. 1A-1H; therefore, identical or similar elements are denoted by same or similar reference numerals. The main difference between the above two manufacturing methods lies in that, in the manufacturing method of the pixel structure in FIGS. 1A-1H, the mask 140 is used to cover the portion of the first semiconductor region 120 which is to be formed on the channel region R to prevent it from being affected during the subsequent treatment procedure. In comparison, the manufacturing method of the pixel structure in FIGS. 2A-2I realizes the purpose of covering using the photoresist material. The following descriptions are provided for explaining the main difference; the similarities between the two methods will not be repeated in the following paragraphs.

Please refer to FIG. 2A, a substrate 100 is provided, and a gate G is formed on the substrate 100. As shown by FIG. 2B, a gate insulating layer GI is formed on the gate G to cover the gate G Subsequently, as shown by FIG. 2C, a source S and a drain D are formed on the gate insulating layer GI. The source S and the drain D are separated from each other and respectively cover opposite sides of the gate insulating layer GI above the gate G.

As shown by FIG. 2D, a semiconductor layer SE is formed on the gate insulating layer GI. In the embodiment, the semiconductor layer SE may fully cover the source S, the drain D and the gate insulating layer GI, which should not be construed as a limitation to the invention. Considering from the aspect of high transparency and modulation of high carrier concentration, in the embodiment, the material of the semiconductor layer SE is preferably a metal oxide semiconductor material which is selected from, for example, IGZO; ZnO; SnO; IZO; GZO; ZTO; ITO or a combination thereof, which should not be construed as a limitation to the invention.

Thereafter, a photoresist layer (not shown) is formed on the semiconductor layer SE to cover the semiconductor layer SE. The photoresist layer may be a positive photoresist layer or a negative photoresist layer selectively; the invention provides not limitation to the type of the photoresist material.

Please refer to FIG. 2E, the photoresist layer is patterned to form a first photoresist pattern PR1 and a second photoresist pattern PR2. The first photoresist pattern PR1 and the second photoresist pattern PR2 are formed via, for example, a half tone mask process, which should not be construed as a limitation to the invention. Subsequently, the first photoresist pattern PR1 and the second photoresist pattern PR2 are used as masks for patterning the semiconductor layer SE to form a first semiconductor pattern 120 and a second semiconductor pattern 122 respectively under the first photoresist pattern PR1 and the second photoresist pattern PR2. The first semiconductor pattern 120 is aligned with the first photoresist pattern PR1, and the second semiconductor pattern 122 is aligned with the second photoresist pattern PR2. The first semiconductor pattern 120 is located above the gate G, and first semiconductor pattern 120 contacts a source S and a drain D. The second semiconductor pattern 122 contacts the drain D.

Please refer to FIG. 2F, further to the abovementioned, a portion of the first photoresist pattern PR1 is removed, and the second photoresist pattern PR2 is completely removed so that a photoresist pattern PR1′ is formed on the first semiconductor pattern 120 and exposes the complete second semiconductor pattern 122. The photoresist pattern PR1′ is formed via, for example, an ashing treatment or an etching process for removing the photoresist material, which should not be construed as a limitation to the invention. The photoresist pattern PR1′ covers a portion of the first semiconductor pattern 120 and exposes opposite sides 120a and 120b of the first semiconductor pattern 120. Please note that, in the embodiment, by being covered by the photoresist pattern PR1′, the portion of the covered first semiconductor pattern 120 may be protected from being affected during the subsequent treatment procedure.

Please refer to FIG. 2G, a treatment procedure is performed to the first semiconductor pattern 120 and the second semiconductor pattern 122 so that the both sides 120a and 120b of the exposed first semiconductor pattern 120 are respectively formed into a first conductive region C1 and a second conductive region C2, allowing the second semiconductor pattern 122 to be formed into a pixel electrode pattern PE. In the embodiment, the above treatment process is a hydrogen plasma doping treatment, which should not be construed as a limitation to the invention. In other embodiments, the above treatment procedure may be a nitrogen plasma doping treatment, an ultra-violet (UV) curing treatment or a heating treatment. Likewise, in the embodiment, the first conductive region C1 covers the source S to be electrically connected to the source S; the second conductive region C2 covers the drain D to be electrically connected to the drain D, and the pixel electrode pattern PE covers the drain D to be electrically connected to the drain D; however, the invention is not limited thereto. The metal oxide semiconductor region which is covered by the photoresist pattern PR1′ may be protected by the photoresist pattern PR1′ and therefore retains the semiconductor characteristic to be formed into the channel region R. As shown by FIG. 2G, the channel region R is located above the gate G between the first conductive region C1 and the second conductive region C2. Finally, after the photoresist pattern PR1′ is removed, the manufacture of a pixel structure 20 of the embodiment is completed.

In addition, please refer to FIG. 2H, a protecting layer 160 may be further formed on the gate insulating layer GI. In the embodiment, the protecting layer 160 covers a channel region R. Then, as shown by FIG. 2I, a common electrode pattern CE may be formed on the protecting layer 160. The common electrode pattern CE is located above the pixel electrode pattern PE. When the pixel structure 20 is applied in the FFS LCD, at least one of the pixel electrode pattern PE and the common electrode pattern CE may have a plurality of slits and a plurality of branch electrode patterns. In the embodiment, the pixel electrode pattern PE is a block-shaped electrode pattern, and the common electrode pattern CE has a plurality of branch electrode patterns.

Likewise, the manufacturing method of the pixel structure of the embodiment may allow the channel region R and the pixel electrode pattern PE to be formed at the same time. Accordingly, the method helps to reduce the photomask lithographic steps for manufacturing the pixel structure 20, thereby lowering the manufacturing cost and improving productivity.

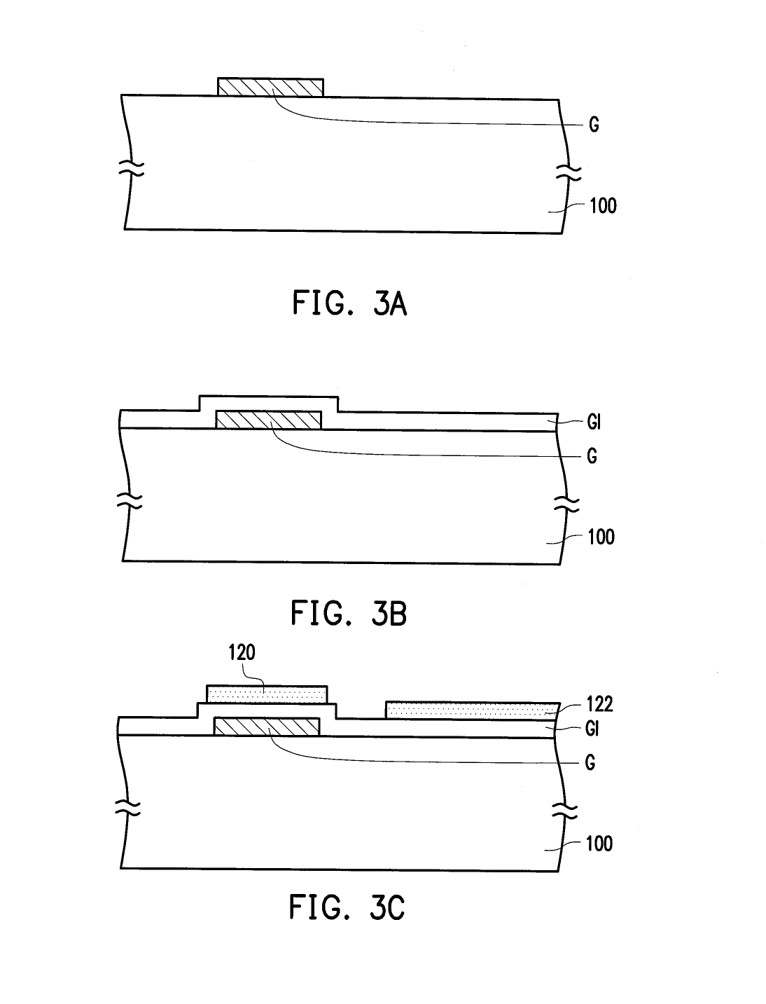

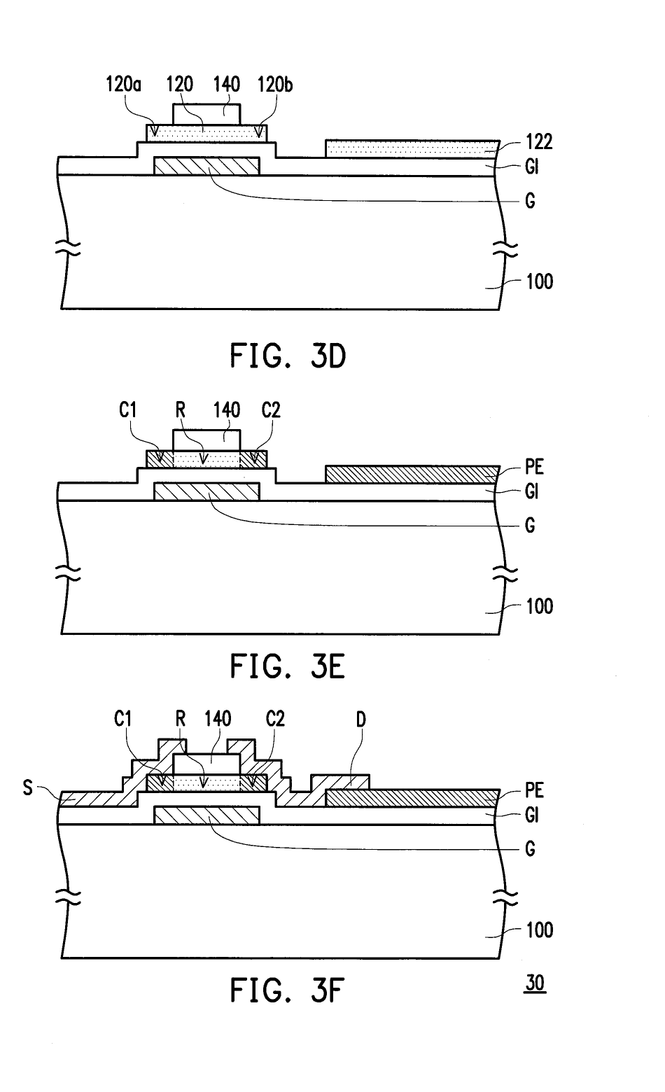

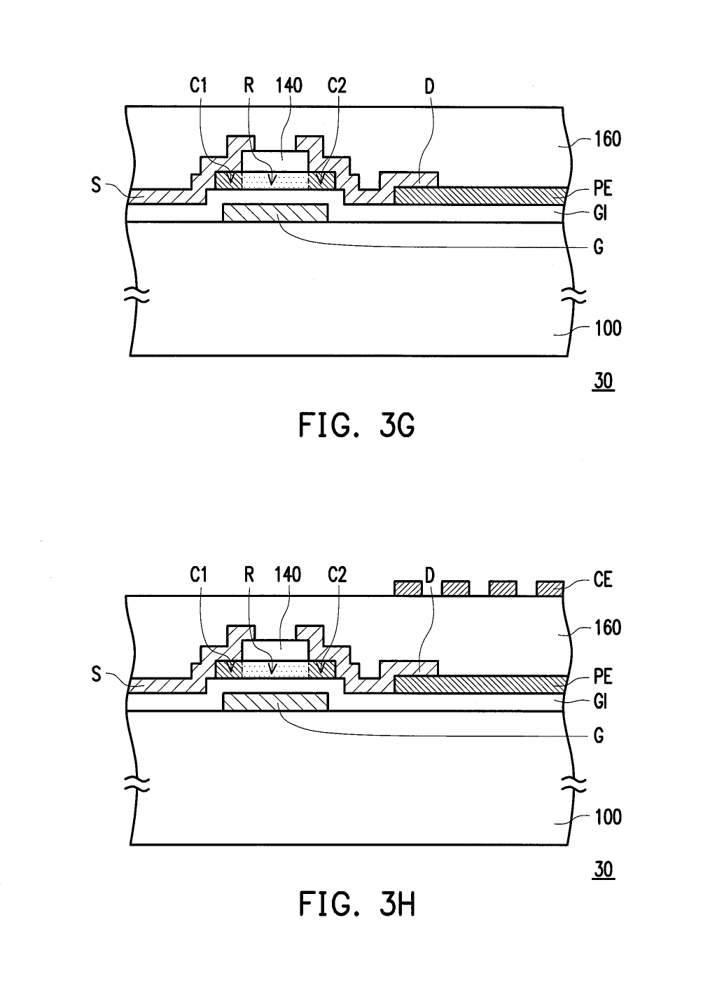

FIGS. 3A-3H are cross-sectional schematic views illustrating a manufacturing method of a pixel structure according to a third embodiment of the invention. The manufacturing method of the pixel structure in FIGS. 3A-3H is similar to the manufacturing method of the pixel structure in FIGS. 1A-1H; therefore, identical or similar elements are denoted by same or similar reference numbers. The main difference between the above two methods lies in that, in the manufacturing method of the pixel structure in FIGS. 1A-1H, the first semiconductor pattern 120 and the second semiconductor pattern 122 are formed after the formation of the source S and the drain D. To the contrary, in the manufacturing method of the pixel structure in FIGS. 3A-3H, the first semiconductor pattern 120 and the second semiconductor pattern 122 are formed before the formation of the source S and the drain D.

Please refer to FIG. 3A, a substrate 100 is provided, and a gate G is formed on the substrate 100. As shown by FIG. 3B, a gate insulating layer GI is formed on the gate G to cover the gate G.

Then, as shown by FIG. 3C, a first semiconductor layer 120 and a second semiconductor pattern 122 are formed on the gate insulating layer GI. The first semiconductor layer 120 is located above the gate G Considering from the aspect of high transparency and modulation of high carrier concentration, in the embodiment, the material of the first semiconductor layer 120 and the second semiconductor pattern 122 is preferably a metal oxide semiconductor material.

Please refer to FIG. 3D, a mask 140 is formed on the first semiconductor pattern 120. The mask 140 covers a portion of the first semiconductor pattern 120 and exposes opposite sides 120a and 120b of the first semiconductor pattern 120. The mask 140 may protect a portion of the covered first semiconductor pattern 120 to prevent it from being affected during the subsequent treatment procedure.

Then, as shown by FIG. 3E, a treatment procedure is performed to the first semiconductor pattern 120 and the second semiconductor pattern 122 so that the both sides 120a and 120b of the exposed first semiconductor pattern 120 are respectively formed into the first conductive region C1 and the second conductive region C2, allowing the second semiconductor pattern 122 to be formed into the pixel electrode pattern PE. In the embodiment, the above treatment procedure is a hydrogen plasma doping treatment, which should be not construed as a limitation to the invention. In other embodiments, the above treatment procedure may also be a nitrogen plasma doping treatment, an ultra-violet (UV) curing treatment or a heating treatment. The metal oxide semiconductor region covered by the mask 140 may be protected by the mask 140 and therefore retains the semiconductor characteristic to be formed into the channel region R.

Subsequently, as shown by FIG. 3F, the source S and the drain D are formed on the gate insulating layer GI, thereby completing the manufacture of a pixel structure 30 of the embodiment. In the embodiment, the source S covers the first conductive region C1 and both of them are electrically connected to each other, and the drain D covers the second semiconductor region C2 and both of them are electrically connected to each other. In addition, the drain D further covers the pixel electrode pattern PE and both of them are electrically connected to each other. After the above steps are performed, the manufacture of the pixel structure 30 of the embodiment is completed.

In addition, please refer to FIG. 3G; a protecting layer 160 may be further formed on the gate insulating layer GI. The protecting layer 160 covers the mask 140. Thereafter, as shown by FIG. 3H, a common electrode pattern CE may be formed on the protecting layer 160. The common electrode pattern CE is located above the pixel electrode pattern PE. When the pixel structure 30 is applied in the FFS LCD, at least one of the pixel electrode pattern PE and the common electrode pattern CE may have a plurality of slits and a plurality of branch electrode patterns. In the embodiments, the pixel electrode pattern PE is a block-shaped electrode pattern, and the common electrode pattern CE has a plurality of branch electrode patterns. Compared with the conventional manufacturing method of a pixel structure, the manufacturing method of the pixel structure of the embodiment may allow the channel region R and the pixel electrode pattern PE to be formed at the same time. Accordingly, the above method helps to reduce the photomask lithographic steps for manufacturing the pixel structure 30, thereby lowering the manufacturing cost and improving productivity.

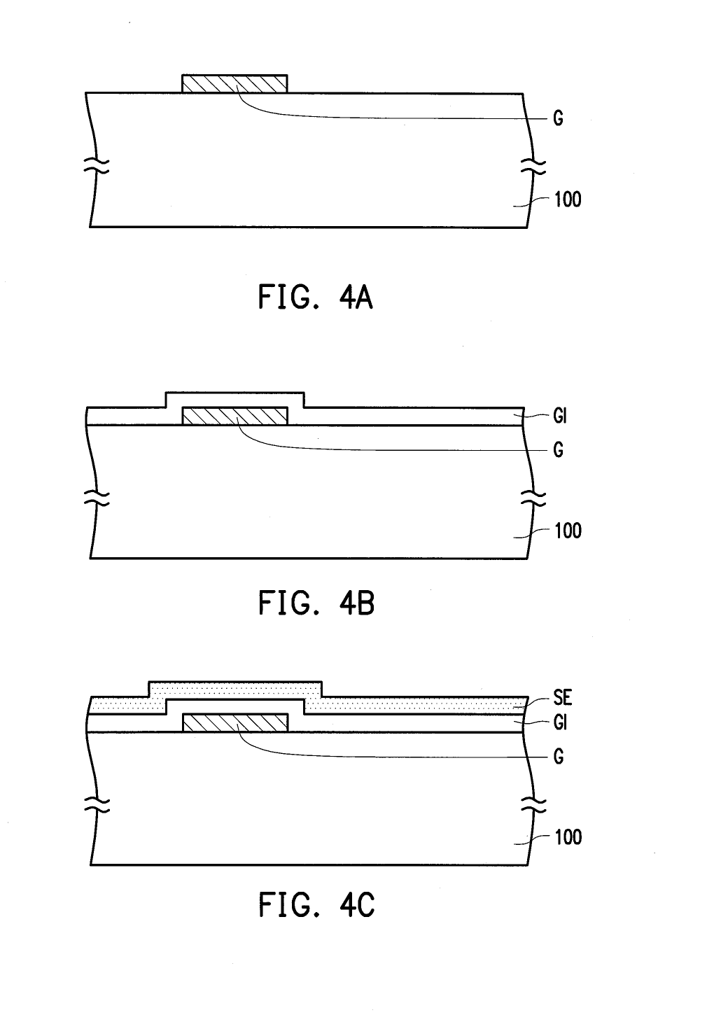

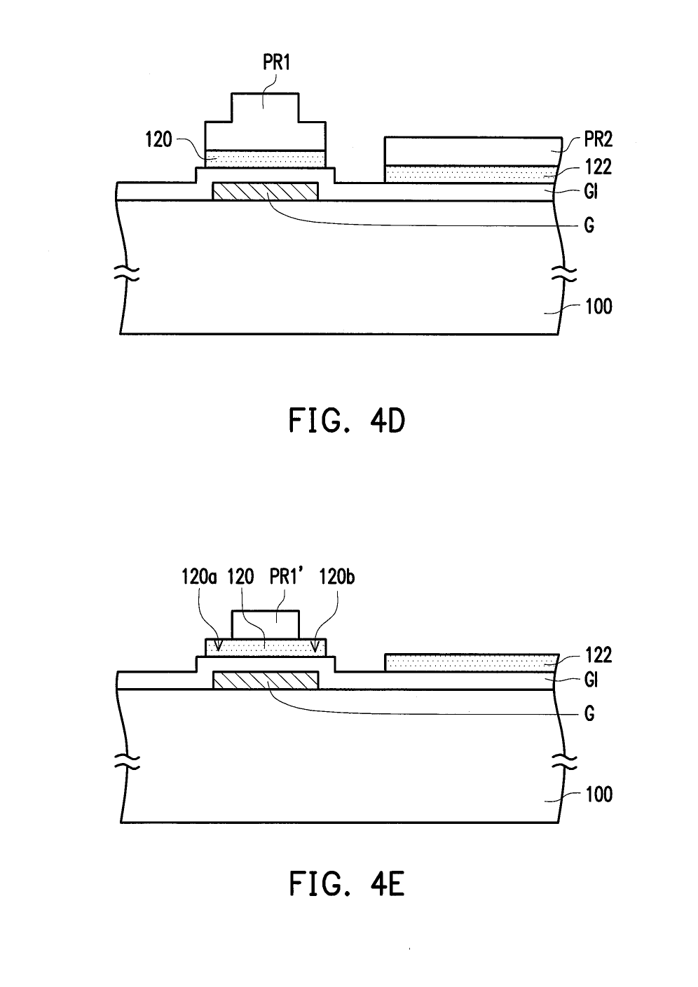

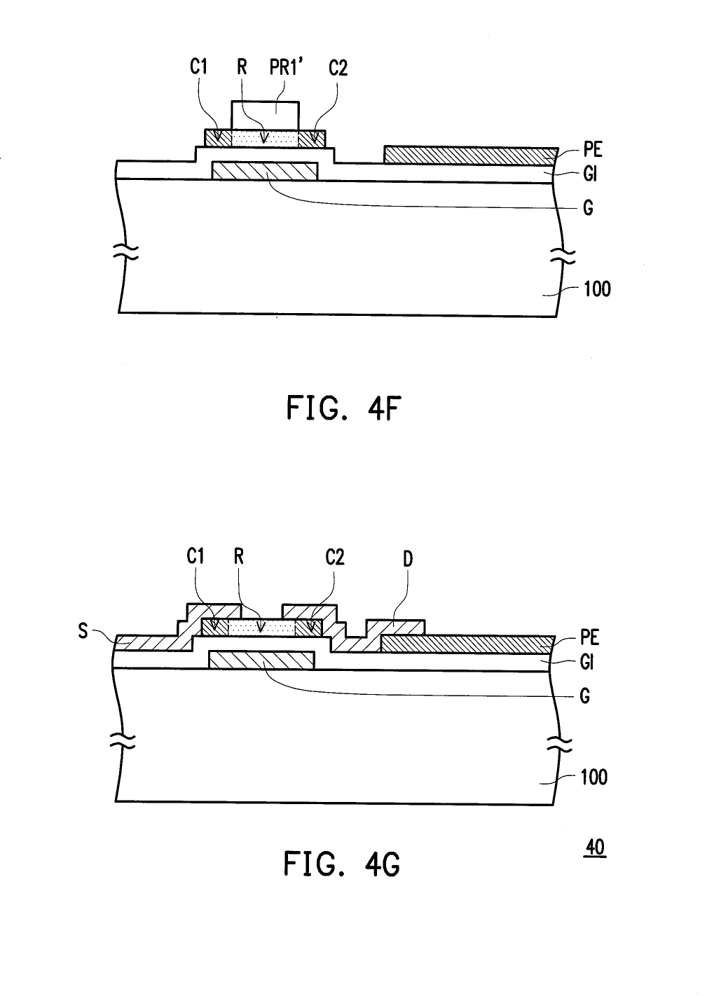

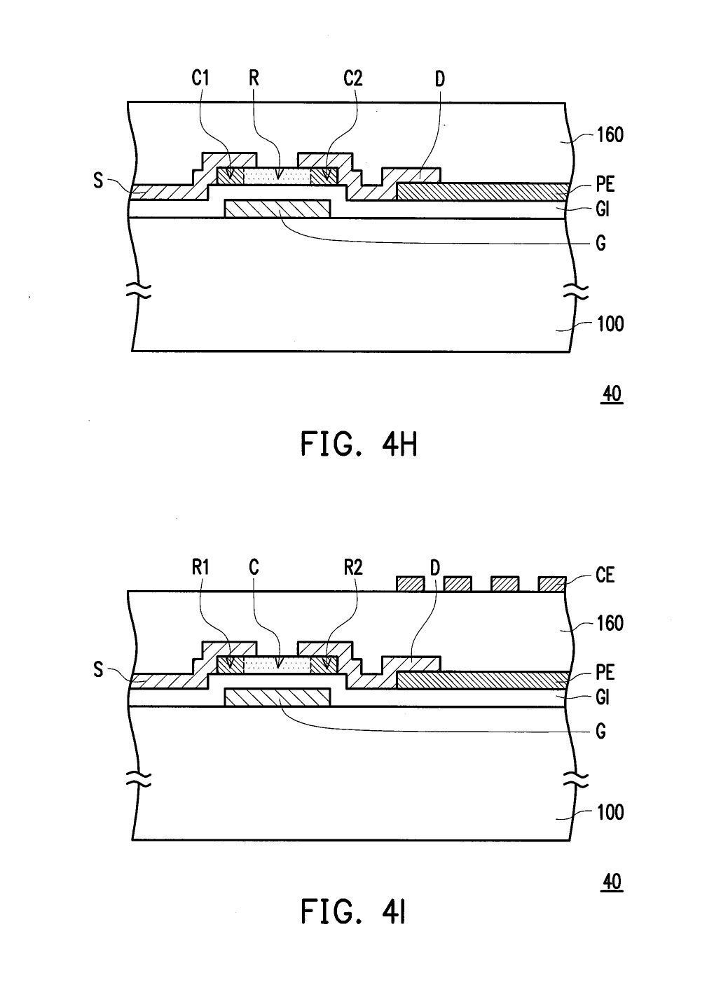

FIGS. 4A-4I are cross-sectional schematic views illustrating a manufacturing method of a pixel structure according to a fourth embodiment of the invention. The manufacturing method of the pixel structure of FIGS. 4A-4I is similar to the manufacturing method of the pixel structure of FIGS. 3A-3H; therefore, identical or similar elements are denoted by same or similar reference numbers. The main difference of the above two methods lies in that, in the manufacturing method of the pixel structure of FIGS. 3A-3H, the mask 140 is used to cover a portion of the first semiconductor pattern 120 which is to be formed into the channel region R. In the manufacturing method of the pixel structure of FIGS. 4A-4I, the photoresist material is used to realize the purpose of covering.

Please refer to FIG. 4A, a substrate 100 is provided, and a gate G is formed on the substrate 100. As shown by FIG. 4B, a gate insulating layer GI is formed on the gate G to cover the gate G.

Then, as shown by FIG. 4C, a semiconductor layer SE is formed on the gate insulating layer GI. In the embodiment, the semiconductor layer SE may fully cover the gate insulating layer GI, which should not be construed as a limitation to the invention. In the embodiment, the material of the semiconductor layer SE is preferably a metal oxide semiconductor material.

Then, a photoresist layer (not shown) is formed on the semiconductor layer SE to cover the semiconductor layer SE. The photoresist layer may be a positive photoresist layer or a negative photoresist layer selectively; the invention provides no limitation to the type of the photoresist material.

Please refer to FIG. 4D, a photoresist layer is patterned to form a first photoresist pattern PR1 and a second photoresist pattern PR2. The first photoresist pattern PR1 and the second photoresist pattern PR2 are formed via, for example, a half tone mask process, which should not be construed as a limitation to the invention. Then, the first photoresist pattern PR1 and the second photoresist pattern PR2 are used as a mask for patterning the semiconductor layer SE to form a first semiconductor pattern 120 and a second semiconductor pattern 122 respectively under the first photoresist pattern PR1 and the second photoresist pattern PR2. The first semiconductor pattern 120 is aligned with the first photoresist pattern PR1, and the second semiconductor pattern 122 is aligned with the second photoresist pattern PR2. The first semiconductor pattern 120 is located above the gate G.

Subsequently, as shown by FIG. 4E, a portion of the first photoresist pattern PR1 is removed and the second photoresist pattern PR2 is fully removed so that a photoresist pattern PR1′ is formed on the first semiconductor pattern 120 and the second semiconductor pattern 122 is completely exposed. The photoresist pattern PR1′ covers a portion of the first semiconductor pattern 120 and exposes opposite sides 120a and 120b of the first semiconductor pattern 120. Please note that, in the embodiment, by being covered by the photoresist pattern PR1′, the portion of the covered first semiconductor pattern 120 may be protected from being affected during the subsequent treatment procedure.

Thereafter, as shown by FIG. 4F, a treatment procedure is performed to the first semiconductor pattern 120 and the second semiconductor pattern 122 so that the both sides 120a and 120b of the exposed first semiconductor pattern 120 are respectively formed into a first conductive region C1 and a second conductive region C2, allowing the second semiconductor pattern 122 to be formed into a pixel electrode pattern PE. In the embodiment, the treatment procedure is a hydrogen plasma doping treatment, which should not be construed as a limitation to the invention. In other embodiments, the above treatment procedure may also be a nitrogen plasma doping treatment, an ultra-violet (UV) curing treatment or a heating treatment. The metal oxide semiconductor region which is covered by the photoresist pattern PR is protected by the photoresist pattern PR and therefore retains the semiconductor characteristic to be formed into a channel region R. As shown by FIG. 4F, the channel region R is located above the gate G and between the first conductive region C1 and the second conductive region C2. After the above treatment procedure is competed, the photoresist pattern PR1′ is removed.

Then, as shown by FIG. 4G, a source S and a drain D are formed on the gate insulating layer GI, thereby completing the manufacture of a pixel structure 40 of the embodiment. In the embodiment, the source S covers the first conductive region C1 and both of them are electrically connected to each other. The drain D covers the second conductive region C2 and both of them are electrically connected to each other. In addition, the drain D further covers the pixel electrode pattern PE and both of them are electrically connected to each other.

Furthermore, please refer to FIG. 4H; a protecting layer 160 may be further formed on the gate insulating layer GI. In the embodiment, the protecting layer 160 covers the mask 140. Then, as shown by FIG. 4I, a common electrode pattern CE may be formed on the protecting layer 160. The common electrode pattern CE is located above the pixel electrode pattern PE. When the pixel structure 40 is applied in the FFS LCD, at least one of the pixel electrode pattern PE and the common electrode pattern CE may have a plurality of slits and a plurality of branch electrode patterns.

Likewise, compared with conventional manufacturing methods of the pixel structure, the manufacturing method of the pixel structure in the embodiment may allow the channel region R and the pixel electrode pattern PE to be formed at the same time. Accordingly, the above method helps to reduce the photomask lithographic steps for manufacturing the pixel structure 40, thereby lowering the manufacturing cost and improving productivity.

In summary, in the manufacturing method of the pixel structure of the invention, a metal oxide semiconductor material is used as a semiconductor layer of the pixel structure. The metal oxide semiconductor material has high electron mobility, high transparency and adjustable conductivity which may be adjusted according to the change of the hydrogen doping concentration. Based on the above, the manufacturing method of the pixel structure of the invention may allow the channel region and the pixel electrode pattern to be formed at the same time, thereby effectively reducing the photomask lithographic steps for manufacturing the pixel structure and consequently lowering manufacturing cost and improving productivity.

1. A manufacturing method of a pixel structure, comprising the following steps:
forming a gate on a substrate;
forming a gate insulating layer on the substrate to cover the gate;
forming a source and a drain on the gate insulating layer;
forming a first semiconductor pattern and a second semiconductor pattern on the gate insulating layer, wherein the first semiconductor pattern is located above the gate and the first semiconductor pattern contacts the source and the drain, and the second semiconductor pattern contacts the drain;
forming a mask on the first semiconductor pattern, the mask exposing both sides of the first semiconductor pattern; and
performing a treatment procedure so that the both sides of the exposed first semiconductor pattern being formed into a first conductive region and a second conductive region, and the second semiconductor pattern being formed into a pixel electrode pattern, and the first semiconductor pattern covered by the mask being formed into a channel region, wherein the channel region is located between the first conductive region and the second conductive region, the first conductive region is electrically connected to the source, the second conductive region is electrically connected to the drain, and the pixel electrode pattern is electrically connected to the drain.

2. The method of claim 1, wherein the first semiconductor pattern and the second semiconductor pattern are formed after the source and the drain are formed.

3. The method of claim 2, further comprising:
forming a protecting layer on the gate insulating layer, the protecting layer covering the mask; and
forming a common electrode pattern on the protecting layer, the common electrode pattern being located above the pixel electrode pattern.

4. The method of claim 2, wherein the mask is a photoresist pattern, and the mask is removed after the treatment procedure is performed.

5. The method of claim 4, further comprising:
forming a protecting layer on the gate insulating layer, the protecting layer covering the channel region; and
forming a common electrode pattern on the protecting layer, the common electrode pattern being located above the pixel electrode pattern.

6. The method of claim 1, wherein the source and the drain are formed after the first semiconductor pattern and the second semiconductor pattern are formed.

7. The method of claim 6, further comprising:
forming a protecting layer on the gate insulating layer, the protecting layer covering the mask; and
forming a common electrode pattern on the protecting layer, the common electrode pattern being located above the pixel electrode pattern.

8. The method of claim 6, wherein the mask is a photoresist pattern, the mask is removed after the treatment procedure is performed and before the source and the drain are formed.

9. The method of claim 7, further comprising:
forming a protecting layer on the gate insulating layer; and
forming a common electrode pattern on the protecting layer, the common electrode pattern being located above the pixel electrode pattern.

10. The method of claim 1, wherein the treatment procedure comprises a hydrogen plasma doping treatment, a nitrogen plasma doping treatment, an ultra-violet (UV) curing treatment or a heating treatment.

11. The method of claim 1, wherein a material of the first semiconductor pattern is the same as a material of the second semiconductor pattern, and the material is a metal oxide semiconductor material.

12. A pixel structure, comprising:
a substrate;
a gate located on the substrate;
a gate insulating layer covering the gate;
a source and a drain located on the gate insulating layer;
a semiconductor pattern located above the gate and contacting the source and the drain, wherein the semiconductor pattern comprises:
a first conductive region located at a side of the semiconductor pattern and electrically connected to the source;
a second conductive region located at another side of the semiconductor pattern and electrically connected to the drain; and
a channel region located above the gate between the first conductive region and the second conductive region; and
a pixel electrode pattern having the same material and being the same film layer with the second conductive region of the semiconductor pattern, and the pixel electrode pattern being electrically connected to the drain via the second conductive region.

13. The pixel structure according to claim 12, wherein the source is located under the first conductive region of the semiconductor pattern, and the drain is located under the second conductive region of the semiconductor pattern.

14. The pixel structure according to claim 12, wherein the source is located above the first conductive region of the semiconductor pattern, and the drain is located above the second conductive region of the semiconductor pattern.

15. The pixel structure according to claim 12, further comprising:
a protecting layer located above the gate insulating layer; and
a common electrode pattern located on the protecting layer and above the pixel electrode pattern.
